(19) United States
(12) Patent Application Publication
(10) Pub. No.: US 2021/0126025 A1
(43) Pub. Date: Apr. 29, 2021

(54) Imaging Method and Apparatus

(71) Applicant: Monash University, Victoria (AU)

(72) Inventors: Simon Kennedy, Clayton (AU); Daniel Morrison, Clayton (AU); Jean-Michel Redoute, Clayton (AU); Mehmet Rasit Yuce, Clayton (AU)

(73) Assignee: Monash University, Victoria (AU)

(21) Appl. No.: 16/617,349

(22) PCT Filed: May 31, 2018
(86) PCT No.: PCT/AU2018/050533

§ 371 Date: Nov. 26, 2019

(30) Foreign Application Priority Data
May 31, 2017 (AU) 2017902066

(51) Int. Cl. H01L 27/146

(52) U.S. Cl. CPC H01L 27/1461; H01L 27/14643; H01L 27/1464; H01L 27/14612

(57) ABSTRACT

An imaging apparatus and method, the apparatus comprising: a semiconductor die; a photosensitive array of photodiodes and single photon avalanche diodes (SPADs), the photodiodes comprising reverse biased diodes; and a front-end circuit coupled to the photosensitive array; and an output for outputting image data from the front-end circuit. The photosensitive array and the front-end circuit are provided in the semiconductor die.

### FIELD OF THE INVENTION

The invention relates to an imaging method and apparatus, of particular but by no means exclusive application as a camera for acquiring hyperspectral 3D images.

### BACKGROUND OF THE INVENTION

Vision sensors for capturing real time three-dimensional (3D) images form the basis of machine learning systems. Autonomous systems require low latency visual data to maximise their performance particularly in urban environments. Micro unmanned aircraft systems (UASs) require sophisticated simultaneous localisation and mapping (SLAM) systems to navigate safely and are severely payload restricted. A monolithic image sensor capable of operating in these environments with increased observational capabilities is desirable to increase system performance and keep weight, power consumption and total system size to a minimum.

Single Photon Avalanche Diodes (SPADs) implemented in standard CMOS processes have attracted attention in recent years. High performance SPAD image sensor arrays have been demonstrated to be able to operate as highly sensitive photo detectors capturing 3D depth data using time-of-flight or high dynamic range imaging using photon counting. SPADs are able to detect, with a finite probability, single photons enabling their use in very low photon rate environments. Non-stereoscopic 3D vision techniques belong to three main groups: triangulation, interferometry and time of flight. SPADs utilise their sensitivity to single photons by operating in time of flight mode to simultaneously measure distances in each pixel. The resultant measurement is capable of pico-second resolution. A SPAD is a type of Avalanche Photo Diode (APD) operated below the breakdown voltage. Standard CMOS photodiodes are essentially diodes that are reverse biased, in which incident light generates electron-hole pairs in the depletion region producing a reverse current. This diode current is proportional to the incident light intensity. APDs were developed in order to increase the gain between the absorbed photons and output carriers. In APDs, photo-generated carriers produce other carriers via an impact ionization process. The resultant current is an amplified response compared to normal photodiodes. Avalanche currents vary greatly and lead to excess noise, so APDs are used with relatively low gain. This limits the ability to detect single-photons.

SPADs exploit multiplication in a different way. With a bias voltage higher than the breakdown voltage, SPADs work in Geiger-mode. A photon generated carrier triggers an avalanche multiplication of carriers. An avalanche corresponds to a large current pulse which requires either active or passive quenching to stop. That is, this impact ionization involves both positive and negative carriers, with an inherent positive feedback effect that, if the electrical field is high enough, makes the carrier multiplication self-sustaining. These properties mean that SPADs are highly sensitive photo sensors able to be used for time-of-flight and photon counting applications.

However, while in normal APDs, turning off the incident light immediately stops the multiplication, SPADs must be reset after each detection event. This reset process—termed quenching—is required to detect a subsequent photon.

SPADs may be implemented in a two-dimensional array producing an image sensor of separate pixels. With an appropriate optical system this array can be used for photon counting or for photon time-of-flight measurements.

The fill factor of the CMOS or other semiconductor process SPAD is a measure of the percentage of the SPAD area that is sensitive to incoming photons. Maximization of this area increases the density of pixels and improves performance. SPADs are unable to achieve high fill factors owing to the associated circuitry per pixel required to quench, bias and process data, while existing CMOS photodiode image sensors have achieved commercially fill factors of approximately 100%. The latter's massive increase in sensitive area means that pixels can be manufactured with increased density, meaning that arrays can have many more pixels in a given area.

Conventional complementary metal oxide semiconductor (CMOS) photodiode cameras are limited in their maximum achievable data rate due to the enormous number of pixels that are required to be read out in each and every frame. The individual pixel bandwidth is limited by this read out rate. Dynamic range is typically limited by identical pixel gain, the finite pixel capacity for photo charge and identical integration time. For machine vision in uncontrolled environments with natural lighting, such as those expected in urban operations, limited dynamic range and bandwidth performance is compromised.

CMOS SPADs offer superior low light performance than CMOS photodiodes. SPAD devices count individual photons over a period of time to determine intensity. Photodiodes operate as a photon integrator discharging the parasitic junction capacitor under incident light. Photodiodes are unable to detect single photon events and instead require many successive events to register a signal.

SPADs are also able to operate in photon time of flight mode. The time of flight of a laser light pulse can be measured; the distance can thus be determined and the distance information used to determine a 3D distance profile of an irradiated object.

Challenges of integration of SPAD sensors in modern deep sub-micron technology still exist and limit the maximum resolution of SPAD cameras. The density of SPAD sensors is limited by their maximum fill factor, even when manufactured in modern deep-sub-micron CMOS technologies, due in part to the extremely high electromagnetic field (>3×108 V/m) associated with the junction and the necessary isolation wells. Each SPAD sensor is required to have a quenching circuit and associated read out systems which typically are significantly more complex than the traditional three or four transistor photodiode front-ends. In comparison commercial back-illuminated photodiode CMOS image sensors are capable of approaching 100% pixel fill factors.

P. Lichtsteiner, C. Posch and T. Delbruck, A 128×128 120 db 30 mw asynchronous vision sensor that responds to relative intensity change (ISSCC 2006 10.1109/ISSCC.2006.1696265) discloses an asynchronous vision sensor system that responds to relative intensity change, but which can detect only asynchronous events.

R. Berner, C. Brandli, M. Yang, S. Liu and T. Delbruck, A 240×180 10 mW 12 us latency sparse-output vision sensor for mobile applications (Symposium on VLSI Circuits 2013, pp. C186-C187, IEEE) disclose a sensor for mobile applications, but the disclosed system cannot operate output instantaneous intensity and is bulky owing to the circuit topology.

F. Guerrieri, S. Tisa, A. Tosi and F. Zappa, Two-Dimensional SPAD Imaging Camera for Photon Counting (IEEE Photonics Journal, 10.1109/JPHOT.2010.2066554) disclose a two-dimensional SPAD imaging camera for photon counting. The disclosed device uses a parallel data output bus requiring a large number of connections to the die.

J. A. Richardson, E. A. G. Webster, L. A. Grant and R. K. Henderson, Scaleable Single-Photon Avalanche Diode Structures in Nanometer CMOS Technology (IEEE Transactions on Electron Devices, 10.1109/TED.2011.2141138) disclose a CMOS SPAD device but not an image capture system.

D. Bronzi, Y. Zou, F. Villa, S. Tisa, A. Tosi and F. Zappa, Automotive Three-Dimensional Vision Through a Single-Photon Counting SPAD Camera (IEEE Transactions on Intelligent Transportation Systems, 10.1109/TITS.2015.2482601) present work where the SPAD and CMOS camera are co-located and output respective data streams.

U.S. Patent Application Publication No. 2016/0240579 discloses a “Stacked Embedded SPAD Image Sensor For Attached 3D Information”, in which a plurality of visible light pixels is arranged in a first semiconductor die and provide colour image data to visible light readout circuitry in a second semiconductor die (that is bonded to the first semiconductor die), and a plurality of infrared pixels each including a SPAD arranged in the first semiconductor die to detect IR light. This arrangement employs micro lenses to reduce the consequential disadvantage of reduced fill factor, back side illumination, and an external ADC to convert analogue output voltage to digital data.

### SUMMARY OF THE INVENTION

According to a first broad aspect of the present invention, there is provided an imaging apparatus, comprising:
a semiconductor die;
a photosensitive array of photodiodes (such as high speed photodiodes) and single photon avalanche diodes (SPADs), the photodiodes comprising reverse biased diodes; and
a front-end circuit coupled to the photosensitive array; and
an output for outputting image data from the front-end circuit;
wherein the photosensitive array and the front-end circuit are provided in the semiconductor die (and hence the same semiconductor die).

It is envisaged that any type of SPAD may be employed, although certain types of SPAD may be advantageous in certain applications, such as SPADs with higher photon detection efficiency at a specific wavelength or lower intrinsic noise to maximise dynamic range. It is envisaged that various embodiments will employ application specific SPADs designed for maximum detection performance in the light wavelength of interest, such as visible or IR.

The ratio of a number of the photodiodes and a number of the SPADs may be, for example, between 2 and 1. However, the number is largely unconstrained. In certain examples, the ratio may be 4 or more photodiodes (e.g. RGB photodiodes) per SPAD (e.g. IR SPAD), but in each example this ratio may be tuned according to the requirements of the intended application.

In an embodiment, the photodiodes and the SPADs are implemented in standard CMOS processes or other suitable semiconductor process. That is, implementation is not limited to CMOS, other semiconductor technologies are also suitable and have different detection performance.

In another embodiment, the photodiodes and the SPADs are arranged in an integrated manner in the semiconductor die.

In an example, the photodiodes and the SPADs are arranged in alternating rows in the semiconductor die. In another example, the photodiodes alternate with the SPADs in rows in the semiconductor die.

In certain embodiments, the photodiodes have an average density in the semiconductor die of approximately 200 per square millimetre.

In particular embodiments, the SPADs have an average density in the semiconductor die of approximately 150 per square millimetre.

In one embodiment, the imaging apparatus further comprises an electric power converter, an auto-bias and/or a temperature sensor.

The front-end circuit may comprise one or more of:
i) a timer for timing the detection of photons,
ii) a photon counter for counting photons detected by the SPADs,
iii) an avalanche quencher for halting avalanche multiplication of carriers in the SPADs,
iv) a reset circuit for resetting the SPADs after detection events,
v) a data serialiser for moving data out of the photosensitive array,
vi) an asynchronous event detector for detecting asynchronous changes in intensity in photons detected by the photodiodes,
vii) an intensity detector for determining instantaneous intensity of photons detected by the photodiodes,
viii) an integrated intensity detector measuring average intensity in photons detected by the photodiodes; and
ix) an analog to digital converter for directly converting photodiode voltage to a digital signal.

For example, in one embodiment, the front-end circuit comprises a timer for timing the detection of photons and a photon counter for counting photons detected by the SPADs, and is configured to determine time of flight based on outputs of the timer and the photon counter.

The imaging apparatus may be configured for acquiring hyperspectral 3D images.

The imaging apparatus may comprise a lens train for focusing incident light to an image on the photosensitive array.

The imaging apparatus may comprise a single lens for focusing incident light to an image on the photosensitive array.

The front-end circuit implements analogue to digital converters (ADCs) for the photodiodes. The front-end circuit may be direct to digital for the SPADs.

In an embodiment, the imaging apparatus further comprises one or more microlenses located over some or all of the photodiodes and the SPADs to increase effective photosensitive area.

In another embodiment, the imaging apparatus further comprises a wavelength selective filer located in the optical path to modify an incident photon spectrum.

In a further embodiment, the photodiodes and the SPADs are configured to be simultaneously independently operated in different modes.

In a certain embodiment, the SPADs are configured to capture time of flight depth data using an illumination source and the photodiodes are configured to capture intensity image data simultaneously.

The SPADs may be configured to capture intensity image data using a photon counting mode and the photodiodes configured to capture intensity image data simultaneously.

In a certain embodiment, the photosensitive array and the front-end circuit are provided on the same side of the semiconductor die with the photosensitive and the front-end circuit array substantially facing the direction of the incident light.

In other embodiment the photosensitive array and the front-end circuit are provided on opposite faces of the semiconductor die with the photosensitive array substantially facing the direction of the incident light.

According to a second broad aspect of the present invention, there is provided an imaging method, comprising:
collecting light with a photosensitive array of photodiodes and single photon avalanche diodes (SPADs), the photodiodes comprising reverse biased diodes; and
outputting image data from the front-end circuit;
wherein the photosensitive array and the front-end circuit are provided in a semiconductor die.

According to a third broad aspect of the present invention, there is provided an imaging method, comprising:
collecting time of flight data using a plurality of single photon avalanche diodes (SPADs) of a photosensitive array, and simultaneously capturing image intensity data using a plurality of photodiodes of the photosensitive array; and
outputting the 3D image data from a front-end circuit;
wherein the photosensitive array and the front-end circuit are provided in a semiconductor die.

According to a fourth broad aspect of the present invention, there is provided an imaging method, comprising:
collecting image intensity data using photon counting mode of a plurality of single photon avalanche diodes (SPADs) of a photosensitive array, and simultaneously capturing image intensity data using a plurality of photodiodes of the photosensitive array; and
outputting the image data from a front-end circuit;
wherein the photosensitive array and the front-end circuit are provided in a semiconductor die.

According to a fifth broad aspect of the present invention, there is provided method of forming an imaging apparatus comprising:
forming, in a semi-conductor die, a photosensitive array of photodiodes and single photon avalanche diodes (SPADs), the photodiodes comprising reverse biased diodes; and
forming, in the semiconductor die, a front-end circuit coupled to the photosensitive array, the front-end circuit having an output for outputting image data from the front-end circuit.

In an embodiment, the method comprises arranging the photodiodes and the SPADs in an integrated manner in the semiconductor die.

In an embodiment, the method comprises arranging the photodiodes and the SPADs in alternating rows in the semiconductor die.

In an embodiment, the method comprises arranging the photodiodes to alternate with the SPADs in rows in the semiconductor die.

It should be noted that any of the various individual features of each of the above aspects of the invention, and any of the various individual features of the embodiments described herein including in the claims, can be combined as suitable and desired.

### BRIEF DESCRIPTION OF THE DRAWING

In order that the invention may be more clearly ascertained, embodiments will now be described, by way of example, with reference to the accompanying drawing, in which:

FIG. 1 is a schematic view of a camera for acquiring hyperspectral 3D images according to an embodiment of the present invention;

FIG. 2 is a schematic view of the front-end circuit of the camera of FIG. 1;

FIG. 3 is a schematic view of a camera for acquiring hyperspectral 3D images according to an embodiment of the present invention;

FIG. 4A is a schematic view of a portion of the array of photodiodes and SPADs of the camera of FIG. 1 or of FIG. 2;

FIG. 4B is an enlarged view of a detail of FIG. 4A, of the array of photodiodes and SPADs of the camera of FIG. 1 or of FIG. 2;

FIG. 5A is a schematic view of a front illuminated sensor according to an embodiment of the present invention;

FIG. 5B is a schematic view of a back illuminated sensor according to an embodiment of the present invention;

FIG. 6 is a layout screen capture of five test photodiode arrays;

FIGS. 7(a) to (e) are cross-section schematic drawings of the five test photodiode arrays of FIG. 6;

FIG. 8 is a schematic view of the CMOS photodiode pixel front-end circuitry used in a sensor according to an embodiment of the present invention;

FIG. 9 is a cross-section diagram of a SPAD;

FIG. 10 is a schematic view of the SPAD pixel active quenching and rechange front-end circuitry used in a sensor according to an embodiment of the present invention;

FIG. 11 is a block diagram of a SPAD/photodiode image sensor according to an embodiment of the present invention;

FIG. 12 is an integrated circuit microphotograph of the image sensor of FIG. 11;

FIGS. 13(a)-(b) are images of a 3D camera integrated with the sensor of FIGS. 11 and 12;

FIG. 14(a) is an image of a test setup to measure the uniformity of the photodiode array to a large positive spatio-temporal intensity change;

FIG. 14(b) is block diagram of the test setup of FIG. 14(a);

FIG. 14(c) are images obtained from the setup of FIG. 14(a);

FIG. 15 shows example images from the camera of FIG. 13 in photon counting mode;

FIG. 16 shows an example image from the camera of FIG. 13 in the time of light depth imaging mode;

FIG. 17(a) is an image of a test setup for demonstration of combined SPAD and Photodiode Image capture;

FIG. 17(b) is a block diagram of the setup of FIG. 17(a);

FIG. 18(a) shows images of a moving ball using logarithmic response photodiode pixel;

FIG. 18(b) is an image produced in the SPAD photon counting mode;

FIG. 19 shows images captured by the Spatio-Temporal Event Camera of a moving ball of positive spatio-temporal events.

FIG. 20 shows images captured by the Spatio-Temporal Event Camera.

FIGS. 21(a)-(b) are an image and a diagram respectively of a test setup showing camera and desk fan.

FIGS. 22(a), (b) and (c) show images captured with the setup of FIGS. 21(a) and (b) using (a) instantaneous logarithmic capture, (b) conventional global shutter capture and (c) SPAD photon counting;

FIG. 23 is a series of captured images; and

FIG. 24 is a further series of captured images.

### DETAILED DESCRIPTION OF EMBODIMENTS

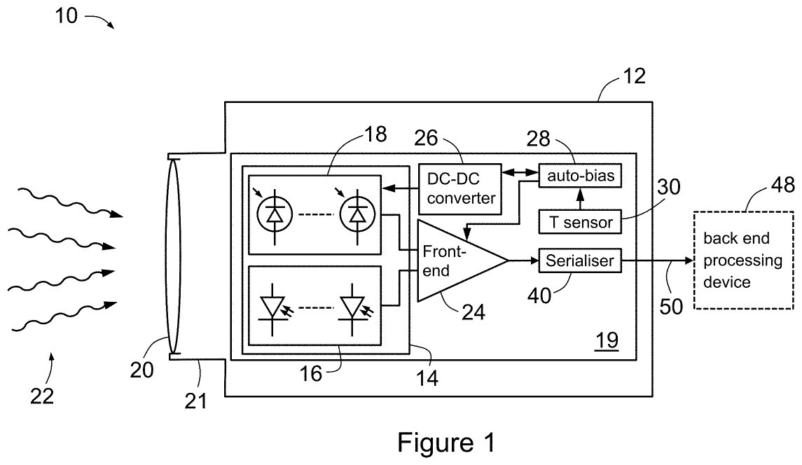

FIG. 1 is a schematic view of a camera 10 for acquiring hyperspectral 3D images according to an embodiment of the invention. Camera 10 includes a housing 12 and an integrated array 14 of photodiodes 16 and SPADs 18, mounted on a die 19 within housing 12. Camera 10 includes a lens train of one or more lenses 20 in a lens unit 21 mounted to housing 12. Lens unit 21 may be detachable from housing 12. Lenses 20 focus incident light 22 to an image on array 14 for detection by array 14.

In this embodiment, SPADs 18 have a 10 μm diameter sensitive area, a total sensor size of 30 μm×30 μm, and a fill factor of 26%. With the respective front-end circuit, this size becomes 40 μm×60 μm with a fill of factor 3.3%. SPADs 18 have an effective sensitivity from 400 nm to 1000 nm, and a peak sensitivity at 532 nm.

SPADs and photodiodes in silicon are sensitive in the wavelength range of approximately 190 nm to 1100 nm, that is, from UV to IR. In other semiconductors, such as HgCdTe, this range can be extended to 14 μm (i.e. very deep IR). Consequently, it will be appreciated that references to ‘light’ herein is intended to embrace those portions of the electromagnetic spectrum—whether visible or not—that may be detected by camera 10 or other embodiments of the invention.

Camera 10 may include a plurality of microlenses (not shown), disposed over some or all of photodiodes 16 and SPADs 18. For example, each microlens may be disposed over a single photodiode 16 or SPAD 18, or—alternatively—over a group of photodiodes 16 and/or SPADs 18. Locating microlenses in the optical path in this manner may be employed to increase effective fill factor.

It will also be appreciated that photodiodes 16 and SPADs 18 are depicted separately solely for clarity. In array 14, even though photodiodes 16 and SPADs 18 are each distributed as respective arrays, these two arrays are integrated (as described further below) such that array 14 constitutes a monolithic sensor. The resultant array 14 of photodiodes 16 and SPADs 16 facilitate the capture of 3D image data, including both intensity and distance information. SPADs 18 facilitate the collection of time of flight information and photon counting, while photodiodes 14 can be used to perform asynchronous event image capture, determine instantaneous intensity (such that camera 10 may, is desired, output instantaneous intensity and hence function essentially as a traditional camera) and determine time-integrated intensity.

Camera 10 also includes front-end circuit 24 coupled to an electric power converter in the form of a DC to DC converter 26, an auto-bias 28 and a temperature sensor 30. These components and array 14 are also provided on die 19, which has the advantage of making the resulting arrangement compact. It will be appreciated, however, that DC to DC converter 26, auto-bias 28 and temperature sensor 30 may be provided other than on die 19, such as on a separate board behind die 19 or elsewhere in housing 12. It should also be appreciated that front-end circuit 24 is shown as separated from photodiodes 16 and SPADs 18 solely for clarity. In array 14, front-end circuit 24 is integrated with photodiodes 16 and SPADs 18 (as described further below), and implements various functions (discussed below), including an analogue to digital converter (ADC) for each of photodiodes 16 to improve the speed of analogue to digital conversion.

DC to DC converter 26 controls the voltage across SPADs 18, while auto-bias 28 controls the bias produced by DC to DC converter 26 to supply SPADs 18 and front-end circuit 24. Auto-bias 28 is configured to allow for temperature variation on the basis of a temperature signal provided by temperature sensor 30.

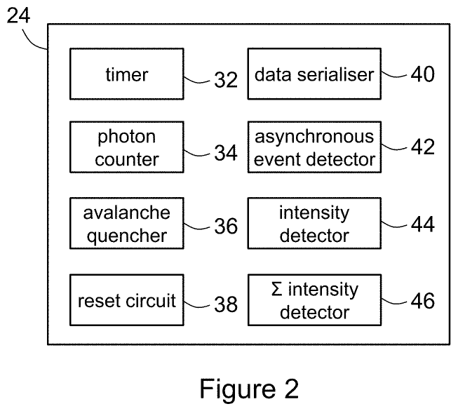

The output of array 14 is passed to front-end circuit 24, which is depicted schematically in FIG. 2. Front-end circuit 24 includes a timer 32 for timing the detection of photons, a photon counter 34 for counting photons detected by SPADs 18, an avalanche quencher 36 for halting the avalanche multiplication of carriers, a reset circuit 38 for resetting SPADs 18 after each detection event, a data serialiser 40 for moving data out of array 14 (thereby reducing the number of data lines required), an asynchronous event detector 42 for detecting the occurrence of asynchronous change in intensity events in photodiodes 16, an intensity detector 44 for determining instantaneous intensity of photons detected by photodiodes 16, and integrated intensity detector 46 for measuring average intensity detected by the photodiodes 16. Data serialiser 40, though implemented in the embodiment as a part of front-end circuit 24, is shown separately from front-end circuit 24 in FIG. 1, to emphasize its logical position in the transmission of outputs signals from front-end circuit 24 to back end processing device 48. Timer 32 and photon counter 34 implement time of flight determination.

The outputs of front-end circuit 24, and hence of camera 10, are outputted to a data processing device 48 as four data streams: three for photodiodes 16 and one for SPADs 18. Data processing device 48 may be in the form of a computer, programmed to perform image data manipulation and analysis, as well as to store and display (such as to a display of data processing device 48 or of another device) an image reconstructed from the image data. In certain variations of this embodiment, however, camera 10 may include data processing device 48, such as in the form of a field programmable gate array (FPGA) or a processor in housing 12, and optionally a display viewable by a user of camera 10.

Camera 10 may be supplied with power either from an external source (such as back end processing device 48) or an internal source (such as a battery, which may be rechargeable) within housing 12. If power is supplied by back end processing device 48, this may be done by connecting camera 10 to a USB of back end processing device 48, such that a cable 50 connecting camera 10 and back end processing device 48 carries image data, control signals and power.

The light incident on the scene or object to be imaged by camera 10 may be from various sources. In some applications, in which—for example—it is sufficient to collect a basic image, the use of ambient light may be acceptable. In other applications, it may be desirable to employ artificial illumination. For example, if it is desired to collect time of flight information, a pulsed light source (such as a pulsed laser source) may be used, in order to provide pulse timing information for transmission to camera 10 (whether directly, via back end processing device 48, or otherwise), so that the pulse timing information can be used, along with outputs from timer 32 and photon counter 34, to perform time of flight determination.

In certain implementations, lenses 20 may be omitted or removed. For example, in some applications, the timing of the source of illumination may be known and that source may illuminate only a single location of the illuminated scene or object. This may be so when a scanned and pulsed laser source is employed. In such cases, front-end circuit 24 or back end processing device 48 may be configured to correlate the known location of illumination with the detection of photons, and reconstruct an image accordingly.

In a biomedical example, the light source may comprise an X-ray scintillator or a tracer, such as is present in positron emission tomography. In such an application, the SPAD array does not require the use of a lens. In microfluidic lab-on-chip devices, the camera may be directly coupled to the micro-reactors to detect florescence of the samples.

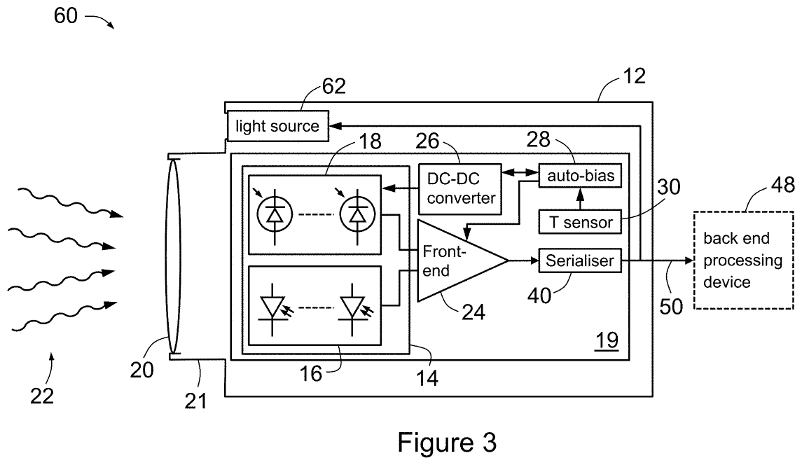

In other embodiments, a light source may be included in the camera. Thus, FIG. 3 is a schematic view of a camera 60 for acquiring hyperspectral 3D images according to another embodiment of the invention. Camera 60 is identical in most respects with camera 10 of FIG. 1, and like features are identified by like reference numerals.

However, camera 60 additionally includes a light source 62. Light source 62 typically comprises a laser, LED or electronic flash unit of the type employed in digital cameras, and is in data communication with front-end circuit 24 and/or back end processing device 48. This facilitates the control, synchronization and/or timing of light source 62. In various implementations of this embodiment, camera 60 may be configured to pulse light source 62 or to pass timing information concerning when light source 62 is illuminated to front-end circuit 24 and/or back end processing device 48.

Light source 62 may also be supplied with power either from an external source (such as back end processing device 48) or an internal source (such as a battery) within housing 12.

In camera 10 of FIG. 1 and camera 60 of FIG. 3, array 14 has 2,560 high speed photodiodes 16 with an event resolution of 5 μs, and 1,920 SPADs with a timing resolution of 1.6 ns, comprising 40×64 photodiode pixels and 40×49 SPAD pixels respectively, or a ratio of photodiode pixels to SPAD pixels of about 1.3 to 1. The overall light detecting dimensions of array 14 are, in this embodiment, about 3.5 mm×3.5 mm. It will be appreciated that the number of rows of photodiodes and SPADs may be varied, and that lower densities of each may be acceptable in some applications. Advantageously the photodiode rows alternate with the SPAD rows in array 14, or that—if rows include both photodiodes and SPADs—the photodiodes alternate with the SPADs. This provides the greatest level of integration of the two types of photo sensing elements. However, it may be acceptable in some embodiments to have a lower level of integration and/or a different ratio of photodiode pixels to SPAD pixels. This may be desired in applications in which the information from the photodiode pixels is more important than that from the SPAD pixels, or vice versa.

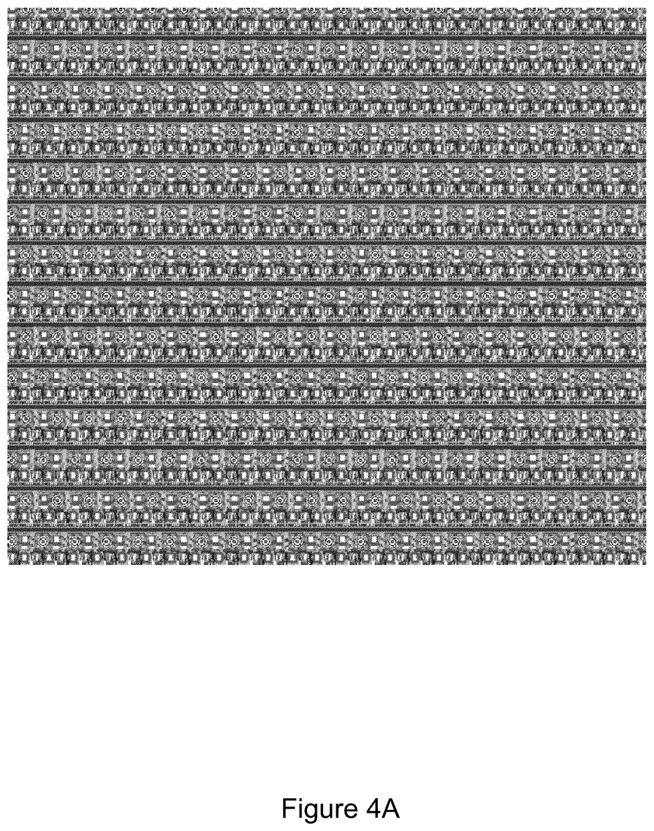

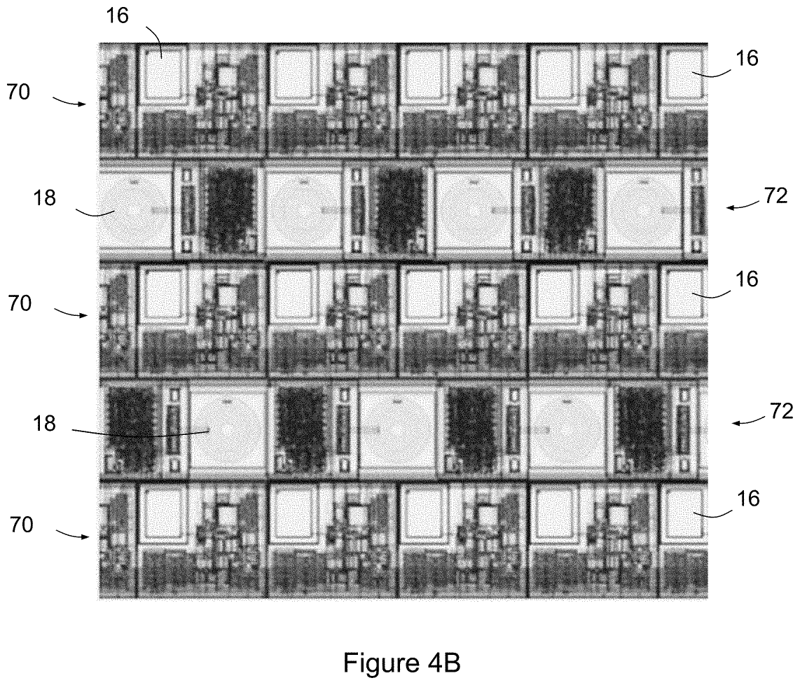

FIG. 4A is a schematic view of a portion of array 14 and front-end circuit 24 of camera 10 of FIG. 1, as arranged in integrated fashion on die 19. FIG. 4B is an enlarged view of a detail of FIG. 4B of array 14 and front-end circuit 24, and depicts approximately 0.5% (that is, about 0.25 mm×0.25 mm) of array 14 and front-end circuit 24. Referring to FIG. 4B, as discussed above, array 14 includes alternating rows 70 of photodiodes 16 and rows 72 of SPADs 18, and front-end circuit 24 occupies essentially the rest of the forwardly directed face of die 19.

The integration of photodiodes 16 and SPAD 18 as a monolithic sensor system facilitates increasing the acquired image data. The resultant array of both photodiodes and SPADs is able to capture 3D image data directly, including both intensity and distance information.

That is, photodiodes 16 can capture different image data simultaneously. In an asynchronous image capture mode, photodiodes 16 output digital events based upon changes in image intensity corresponding to a change in a scene. This asynchronous data is particularly useful for neuromorphic object recognition systems. In an instantaneous mode, photodiodes 16 capture the instantaneous logarithmic intensity with approximately the same response as the human eye. In a traditional integrated intensity mode, photodiodes 16 capture integrated (across time) image data.

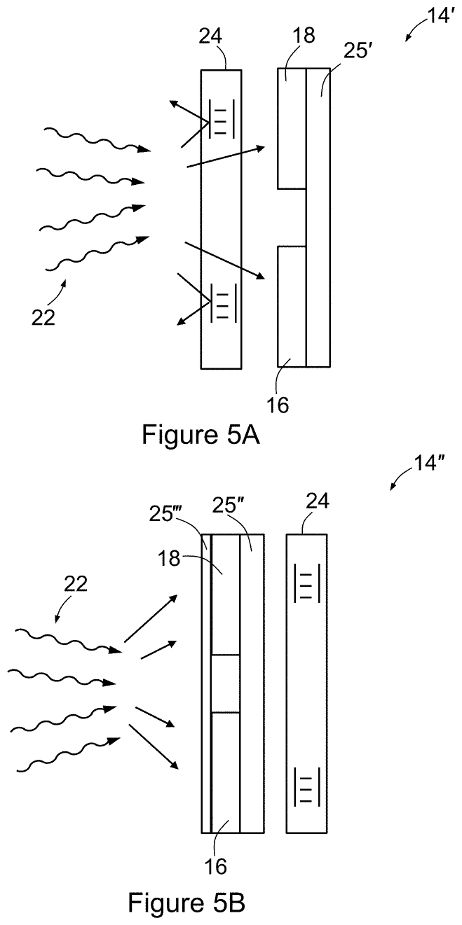

The sensor 14 may be front illuminated as shown by the sensor 14′ of FIG. 5A. In this sensor 14′ the photodiodes 16,18 are located on the same side of circuitry 24 with respect to the semiconductor 25′ and facing the direction of the incident light 22. The light 22 is received from the top of the photodiode.

In another embodiment, sensor 14″ is implemented in a backside illumination configuration as described in FIG. 5B where the photodiodes 16, 18 receive the light from the bottom and the circuitry 24 is located on the other side with respect to the semiconductor 25″. The original base layer of semiconductor 25′″, which is now facing the direction of the incident light, is thinned to make it act as a light-sensitive layer.

In the frontside illuminated sensor 14′ part of the incoming light 22 is reflected by the circuitry 24 which also shields part of the photo sensitive area of the photodiodes 16,18. Conversely, the backside illuminated sensor 14″ has an increased area of absorption of light which in turns leads to an increase sensitivity of the sensor 14″. In practice, the design of backside illuminated sensor 14″ makes cameras fitted with them capable of recording images in lower light levels and with much less digital noise.

Operating Modes: SPADs 18 are able to operate in photon counting mode to capture very low level light intensity data, improving the low light performance of the pixel array. SPADs 18 can operate in time-of-flight mode capturing 3D distance data. Photodiodes 16 capture traditional image sensor data, the instantaneous intensity or asynchronous event data. Photodiodes 16 can operate in event and either instantaneous intensity or integrated intensity modes simultaneously. SPADs 18 are able to work in alternating time-of-flight and photon counting modes.

Thus, array 14 can capture 3D data with essentially no net reduction of photodiode array resolution using SPAD operating modes. The inclusion of SPADs 18 in what would otherwise be a photodiode array reduces the resolution of the photodiode array. That is, SPADs 18 form holes in the Photodiode Array. However, in array 14, photodiodes 16 are able to continuously capture both asynchronous event data and capture full frames of image data (acting essentially as a conventional camera). SPADs 18 operating in time of flight mode capture the 3D distance data. Once this distance measurement has been made, SPADs 18 may operate in photon counting mode, which enables the recovery of the effective photodiode resolution lost to SPADs 18 during time of flight mode.

Array 14 may also extend sensor dynamic range. Photodiodes are most effective in high intensity light conditions, as noise dominates in very low light conditions. However, SPADs 18 have a very high sensitivity to low ambient light conditions, a regime in which photodiodes 16 are significantly less sensitive. The resultant array 14 thus provides a significantly higher dynamic range. From very low light conditions to very bright light conditions, array 14 is able to capture images.

SPADs 18 and photodiodes 16 also facilitate the maximization of the fill factor on die 19. As discussed above, the fill factor of a SPAD measures the percentage of the SPAD area that is sensitive to incoming photons. Maximization of this area increases the density of pixels and improves performance. SPADs 18 are unable to achieve high fill factors owing to the associated per pixel circuitry required to quench, bias and process data. This increase of sensitive area by the inclusion of photodiodes 16 means that array 14 may be manufactured with increased pixel density. Utilising photodiodes 16 may thus increase the photo sensitive area of die 19, as their much higher fill factor can compensate from the lower fill factor of SPADs 18.

The single set of optics and the integration of photodiodes 16 and SPADs 18 for capturing a 3D scene may in some embodiments reduce cost.

Optionally, camera 10 and camera 60 may include one or more physical wavelength filters to select the best or most appropriate wavelengths for imaging, according to application. Such a filer or filters may be attached to lens unit 21 so as to intercept and filter incident light 22.

Optionally, camera 10 and camera 60 may include one or more physical microlenses attached to the surface of the photosensitive areas for imaging, according to application, to increase the effective fill factor.

Prototype image sensors designed with the Silterra C13H32 high voltage (HV) CMOS process are described below

### Photodiode Sensor

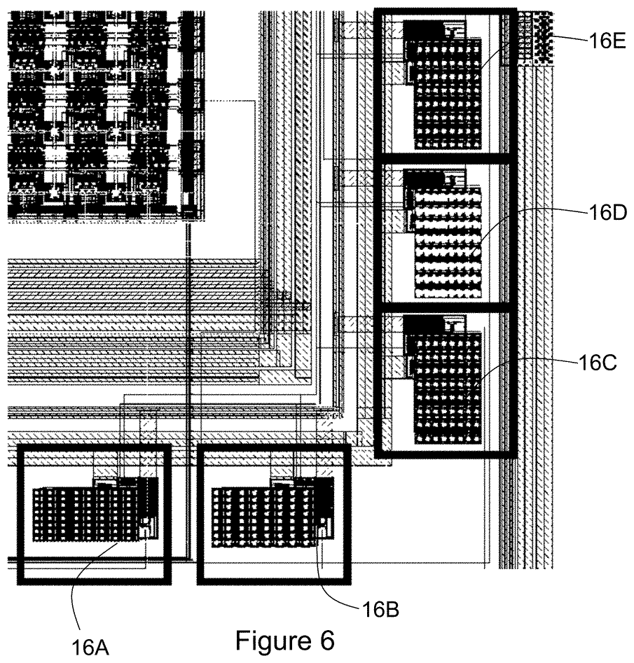

The Silterra C13H32 high voltage (HV) CMOS process had not previously been used for the production of photodiode sensors. Accordingly, five different photodiode sensors 16A-16E were produced so that they could be compared as shown in FIG. 6.

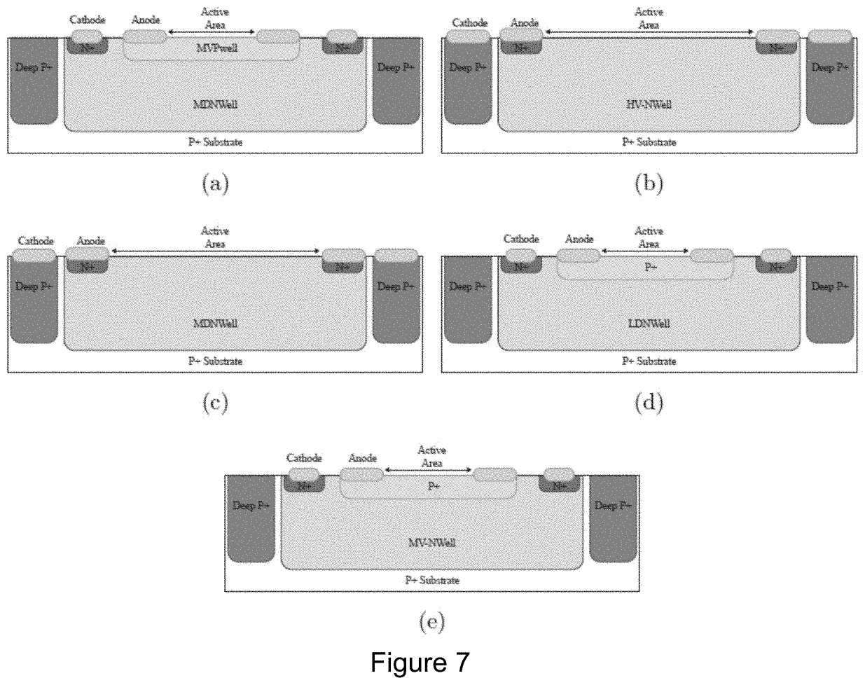

A number of different doped wells were available in this CMOS process. Cross section drawings of the various junctions implemented in photodiode sensors of FIG. 6 are shown in FIGS. 7(a)-(e). These photodiode sensors 16A-16E were evaluated for responsivity though a series of measurements. The diode 16 in FIG. 7(e) formed between the medium voltage n-well and p+ implant junction was the most responsive to light and was therefore selected for use for the photodiode/SPAD 3D image sensor described below. The design is a pinned photodiode, characterised for having low noise, high quantum efficiency and low dark current. As the above described sensors 16A-16E were implemented in a commercial process, so no changes to the doping of these wells was possible to maximise performance limiting the responsivity when compared to state of the art dedicated image sensor processes.

Conventional frame-based images have low complexity pixels that enable high resolution, large fill factor and low cost sensors. The disadvantage of this method of imaging is a high repetition rate of data from pixel where the content has not changed between frames. Biological vision sensors, such as human eyes, operate in a quite different way. When the activity reaches a threshold, the pixel sends a spike to its connected neurons. Spatio-temporal contrast sensors have been proposed previously to mimic this biological behaviour. The logarithmic response of the sensor front-end also matches that of the human eye.

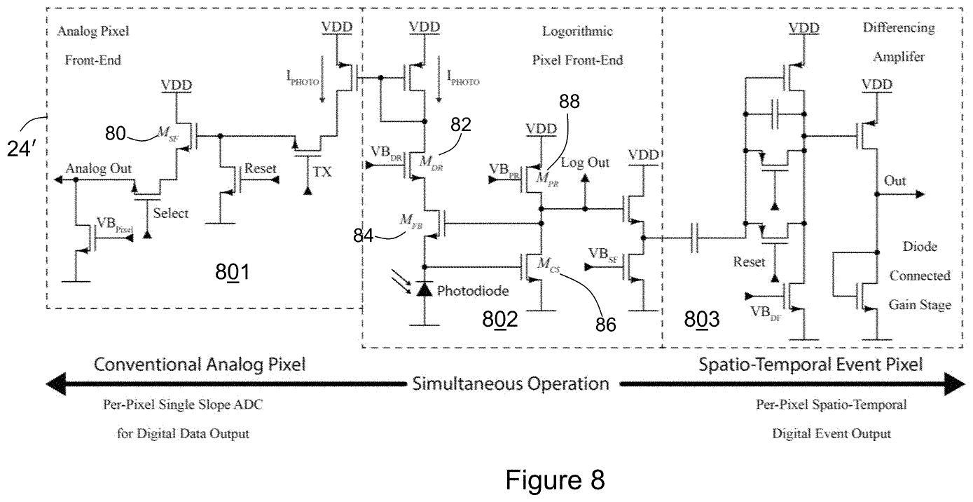

The implemented logarithmic pixel front-end 802, schematically shown in FIG. 8, has an improved front-end design which includes a current mirror to mirror the photo-current through the integrated intensity pixel front-end 801 that enables the continued use of the core voltage devices. The large gate capacitance of the source follower device (M_{SF}) 80 is used to store the integrated intensity voltage. The sensor 16 also has the capability to capture the instantaneous logarithmic intensity of the scene from the pixel front-end circuitry 802. Accordingly, each pixel front-end is capable of simultaneous logarithmic or integrated intensity image capture as well as low latency spatio-temporal digital event capture.

The photoreceptor circuit 24′ provides a much higher bandwidth response when compared to a traditional source follower transimpedance configuration. The logarithmic response provided also enables higher dynamic range event detection. The photocurrent is sourced by a saturated NMOS transistor (M_{FB}) 84. This source follower device is connected to the output of an inverting amplifier (M_{CS}) 86 whose gate is connected to the photodiode. The logarithmic transfer characteristic is produced by (M_{CS}) 86 operating in the weak inversion region. The drain transfer current is hence given by equation (1.1)

$${I}_{D} \approx {I}_{D 0} \frac{W}{L} {e}^{\frac{{V}_{GS} - {V}_{th}}{{nV}_{T}}} , \qquad ( 1.1 )$$

where I_{D0}=current at V_{GS}=Vₜₕ. For M_{CS} 86 to be in weak inversion the photodiode bias must provide V_{GS}≤Vₜₕ.

The inverting common source amplifier is biased through the saturated current source (M_{PR}) 88. This bias sets the output bandwidth of the stage. To improve the isolation between the event and frame imager, a cascode device (M_{DR}) 82 is included. This transimpedance configuration converter, converts the photocurrent logarithmically into a voltage and also holds the photodiode clamped at a virtual ground. The bandwidth of this front-end circuit 802 is enhanced compared to the traditional source follower pixel transimpedance amplifier.

$$Δ {V}_{diff} = A \cdot Δ {V}_{SF} = A \frac{{U}_{T} {κ}_{sf}}{{κ}_{fb}} Δ ln ( {I}_{photo} ) \qquad ( 1.2 )$$

To generate the spatio-temporal events, the pixel contains a continuous time differencing amplifier 803. This differencing amplifier 803 includes two cascaded common source amplifiers to increase the pixel gain. This additional gain stage increases the contrast sensitivity of the pixel improving the photo sensing ability whilst having a minimal impact on maximum pixel bandwidth. The differencing circuit 803 removes any DC present in the output of the logarithmic front-end 802 removing the effect of any mismatch offsets across the array.

The output of this differencing amplifier is compared using positive and negative event threshold voltages supplied via two 10-bit digital to analog converter (DAC). The comparators output the digital event pulses into the pixel logic which controls the local differencing amplifier reset and loads the pulses into the row shift register chain. The row shift register operates at fₒᵤₜ/4096 enabling low latency outputting of events with lower dynamic power dissipation. The synchronous readout circuitry removes the issues of bus arbitration associated with asynchronous readout schemes. The maximum event rate is limited by the clock speed of the row enabling increased maximum event rates when compared to asynchronous designs which require bus arbitration. The data produced by the sensor is sparse enabling high speed data compression and event address encoding to take place on the FPGA.

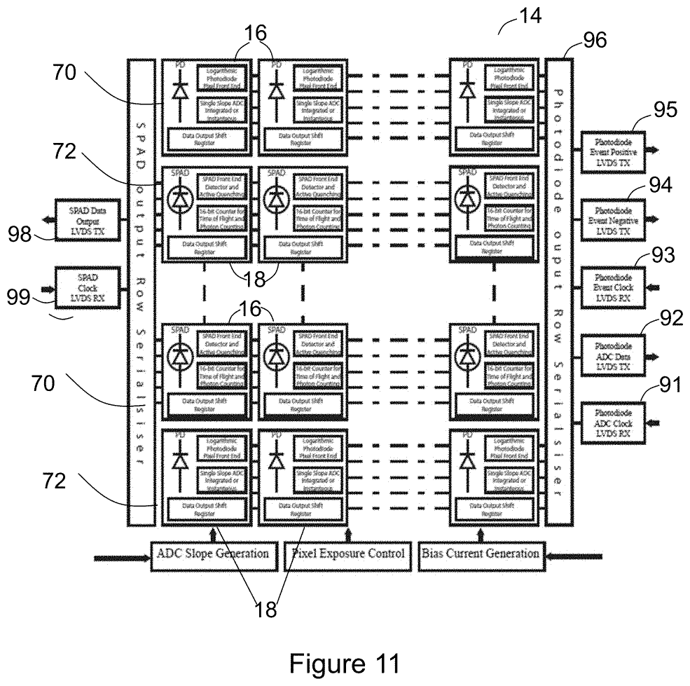

As shown in FIG. 11, the front-end includes a multiplexer to enable either analog output voltage to be sampled by a sample and hold. This voltage is then converted to digital pulses using a per pixel single slope analog to digital converter (ADC). The resultant global shutter or logarithmic imager enables traditional frame based intensity images to be simultaneously captured whilst lower latency event based spatio-temporal images are also captured. The data output from the single slope ADC is encoded in a light-to-time encoding scheme also known as time-to-first spike scheme. This encoding scheme enables the ADC to be interpreted via temporal neuromorphic means or using the pulse interval to perform a time-to-digital conversion, to produce a traditional 10-bit per pixel data word. This pixel level ADCs offer advantages since it eliminates the necessity of high-speed converter and outputting analog signals to external circuitry in addition to offering higher dynamic range. This time-to-first spike data is serialised in each cell and shifted out of the integrated circuit (IC) via a low-voltage differential signalling (LVDS) transmitter 92 to the FPGA for decoding.

Each pixel contains a 20×15 μm² pinned photodiode 16 which was designed in this non-image sensor process. The total pixel area including the front-end 24′ and the photodiode sensor 16 is 50×45 μm² resulting in an effective optical fill factor of 13%.

### SPAD Sensor

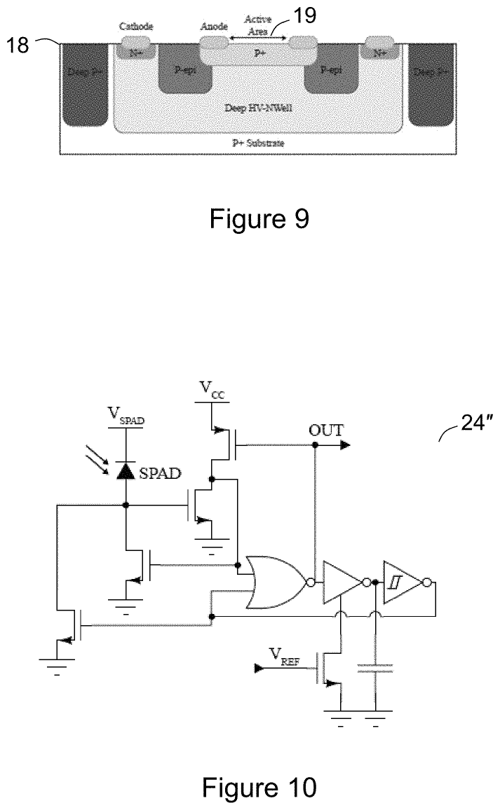

FIG. 9 shows the SPAD sensor junction 19 formed between the p₊ implant anode and the deep high voltage n-well cathode. p-type epitaxy wells are used to minimise lateral breakdown and to minimise dark noise. The breakdown voltage of this junction 19 is approximately 28.5 V and these SPADs are typically operated with a 2-3 V over-voltage bias. Due to the large required isolation wells to minimise cross talk and ensure isolation from the 0.13 μm co-located analog circuitry the active area of each sensor 14 was circular with a diameter of 5 μm. The total pixel area including front-end and counter was 68×40.5 μm² giving an optical fill factor of 0.7%. This limited fill factor could be compensated for using micro-lenses to increase the effective photosensitive area. The enormous optical gain of the SPAD sensor 18 enables detection of single photons with finite probability, enabling operation in very low ambient light environments. SPAD sensors 18 also offer extremely event high timing resolution enabling pico-second detection performance. Timing is limited by the maximum frequency of the time-to-digital converter and maximum detection rate is limited by the recharge and reset time of the SPAD sensor 18.

SPAD sensors 18 require a bias voltage well above the breakdown of the junction to maximise detection performance. When a photon is absorbed by the sensor 18, the photo-generated carrier triggers an avalanche breakdown resulting in a large current ow. This avalanche requires a circuit to quench and restore the junction to detect subsequent photons. In this embodiment, the front-end circuit 24″ contains an active quenching and recharge circuit to minimise the dead time between subsequent avalanche events. A voltage controllable hold time is employed to reduce the likely detection of after-pulsing. A schematic of the front-end 24 “is shown in FIG. 10. Cross-talk between adjacent SPAD sensors 18 is reduced by the inclusion of ground tied deep isolation wells to limit substrate currents.

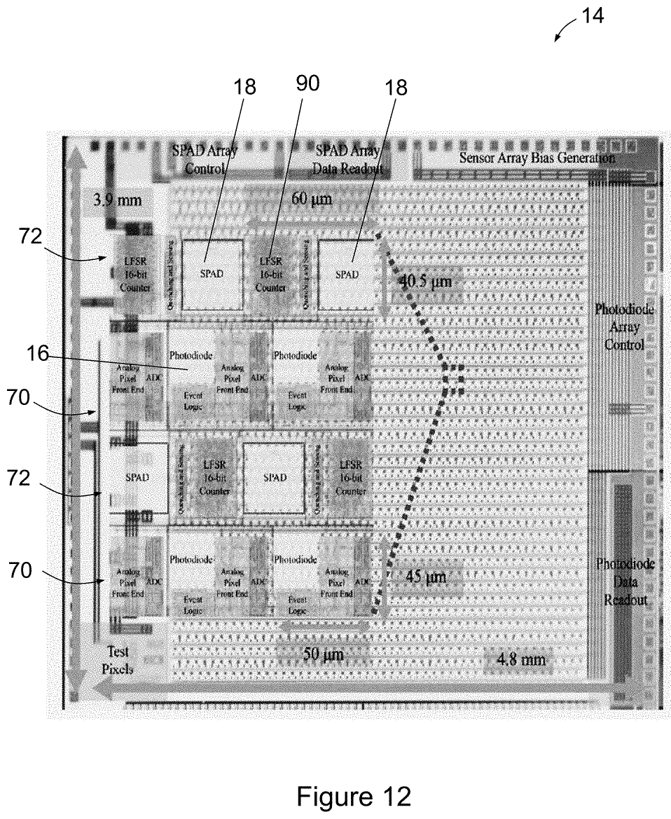

Each SPAD sensor 18 and associated front-end circuitry 24” is co-located with a linear feedback shift register (LFSR) 90 based counter as shown in FIG. 12. This synchronous 16-bit counter is able to be configured for photon counting or time-of-flight measurements. In time-of-flight operation, the counter acts as a time-to-digital converter, measuring the time between the active emission of light and the subsequent detection of the reflected light pulse. The time accuracy of the counter is determined by the clock frequency of the system. The system is designed for a maximum clock frequency of 600 MHz giving a 0.25 m depth resolution. In photon counting mode, the counter sums the number of avalanche events in the frame measuring the local spatio-intensity though the number of detected photons. The LFSR 90, shown in FIG. 12, is able to operate as a shift register and be used to move the data serially though the array to an output LVDS transmitter 98, shown in FIG. 11. This system enables data to be shifted out at the full clock frequency. The FPGA acts as the system clock master providing the array clock via an LVDS receiver 99.

CMOS SPAD sensors 14 have a maximum detection performance in the visible light spectrum. Maximum photon detection efficiency of the SPAD sensors 14 used in this embodiment was measured to be between 400 and 550 nm. The illumination pulses for time of flight measurement was produced by a high power array of 523 nm green LEDs. The requirement for the system to be eye safe, limits the maximum illumination power which restricts the maximum range measurement. The array of 12 emitters produce a total luminous flux of 3240 Im across a 100 degree illumination area. Using a significantly higher power 532 nm green laser under controlled conditions a maximum range of 150 m was measured. The peak sensitivity of CMOS SPADs 14 lying in the visible spectrum restricts the maximum permissible illumination power to maintain eye safety.

### System Design

In the embodiment, the photodiode and SPAD image sensors are configured as independent systems to enable situational optimisation for maximised performance and minimise power consumption. The image sensor 14 is arranged as alternating rows 70,72 of each sensor type 16,18 as shown in FIG. 11. Each photodiode row 70 is connected as a serial chain enabling the shifting of data out into the row output serialiser 96 which then outputs the data via a LVDS transmitter 92, 94, 95. This clock distribution system enables slower local clocks to be distributed throughout the array rows, reducing the dynamic power dissipation significantly. The SPAD array 72 operates synchronously to the input clock 91 and operates as a single shift register with data being moved though the array to the output LVDS transmitter 98 during readout.

LVDS transmitters and receivers (91, 92, 93, 94, 95, 98, 99) were designed to provide high speed data interfaces between the image sensor and FPGA. A conventional design was used for each transceiver enabling data transfers only limited by the maximum clock frequency able to be provided by the FPGA. These differential low swing interfaces enables relatively low power, high data rate read out of the captured image data simultaneously from the four outputs. Two transmitters 94,95 were used for positive and negative spatio-temporal event data, one for the frame based photodiode imaging 92 and one for the SPAD array 98. As described above the prototype image sensor 14 was designed in a Silterra C13H32 0.13 μm HV CMOS process. The prototype sensor is located on a die with total die dimensions of 7.6×4.8 mm. The image sensor 14 proposed here is contained within a 3.9×4.8 mm area. A microphotograph of the image sensor integrated circuit (IC) is shown in FIG. 12.

### Experimental Results

A comparison between the design of the sensor according to the described embodiment and other state of the art CMOS photodiode and SPAD cameras is shown in table 1.1, where:
A: C. Brandli, R. Berner, M. Yang, S.-C. Liu, and T. Delbruck, “A 240×180 130 dB 3 μs Latency Global Shutter Spatiotemporal Vision Sensor,” IEEE Journal of Solid-State Circuits, vol. 49, no. 10, pp. 2333-2341, 2014.
B: J. A. Lenero-Bardallo, R. Carmona-Galan, and A. Rodriguez-Vazquez, “A Wide Linear Dynamic Range Image Sensor Based on Asynchronous Self-Reset and Tagging of Saturation Events,” IEEE Journal of Solid-State Circuits, vol. 52, no. 6, pp. 1605 {1617, 2017.
C: M. S. Cristiano Niclass, H. Matsubara, M. Ogawa, and M. Kagami, “A 0.18-μm CMOS SoC for a 100-m-Range 10-Frame/s 200×96-Pixel Time-of-Flight Depth Sensor,” IEEE Journal of Solid-State Circuits, vol. 49, no. 1, pp. 315{330, 2014. This work: the described embodiment.

TABLE 1.1
Comparison of Performance to Published
State-Of-The-Art in CMOS.

| Parameter | Unit | [7] | [15] | [3] | This Work |
|---|---|---|---|---|---|
| CMOS process | — | 0.18 μm | 0.18 μm | 0.18 μm | 0.13 μm |
| | | MIM CIS | HV | HV | HV |
| SPAD Array | pixels | — | — | 202 × 96 | 49 × 40 |
| resolution | | | | | |
| Photodiode | pixels | 240 × 180 | 96 × 128 | — | 64 × 40 |
| Array | | | | | |
| resolution | | | | | |
| Photodiode | | 51 | 36 | — | 164 |
| Pixel | | | | | |
| Complexity | | | | | |
| SPAD Pixel | | — | — | — | 260 |
| Complexity | | | | | |
| SPAD optical | % | — | — | 70 | 0.7 |
| fill factor | | | | | |
| Photodiode | % | 22 | 10 | — | 13 |
| optical fill | | | | | |
| factor | | | | | |
| Illumination | nm | — | — | 870 | 523 |
| wavelength | | | | | |
| Intensity | fps | 50 | 0.1-200 | 10 | 500 |
| frame rate | | | | | |
| Event Rate | events/s | 50M | 10M | — | 800M |
| Distance range | m | — | — | 100 | 10 |
| (measured) | | | | | |
| Illumination | mW | — | — | 21 | 0.6 |
| power | | | | | |
| SPAD Array | mW | — | — | — | 79 |
| Power | | | | | |
| Consumption | | | | | |
| Photodiode | mW | 14 | 58.6 | — | 140 |
| Array Power | | | | | |
| Consumption | | | | | |

The design according to the described embodiment of the present invention has a much smaller total number of pixels when compared with the three previous works. The increased capabilities of this image sensor require an increased number of devices in each photodiode pixel. This translates to a smaller optical fill factor. The claimed 70% fill factor for the SPAD array in C is misleading as the architecture of the array places a significant proportion of the associated pixel circuitry around the perimeter of the die. The 0.7% SPAD optical fill factor of this sensor 14 is very low and could be increased using an alternative sensor design potentially using a non-circular sensor layout.

The synchronous counter used in the SPAD array is able to detect a single photon each clock cycle when operated in photon counting mode.

The rate of detection of photons is limited by the maximum operating clock rate. The majority of the devices required in each pixel are used in the 16-bit LFSR counter. A reduced depth counter would reduce the pixel circuitry area but reduce the pixel dynamic range and maximum depth measurement.

The designed image sensor 14 is capable of a very high maximum spatio-temporal event rate due to the high speed read out system. Each pixel is able to output a positive and negative event each clock cycle. The maximum intensity frame read out rate is achieved using the logarithmic front-end output rather than the conventional integrated intensity front-end due to the exposure time requirement. The 10-bit single slope ADC requires 40960 clock cycles to complete the conversion and read out using the time to first spike read out system. The maximum speed of the logarithmic pixel level sample and hold circuitry and the bandwidth of the pixels is the limit on maximum frame rate. The conventional global shutter image capture mode requires an extended capture time due to the integration of photo current at the source follower node.

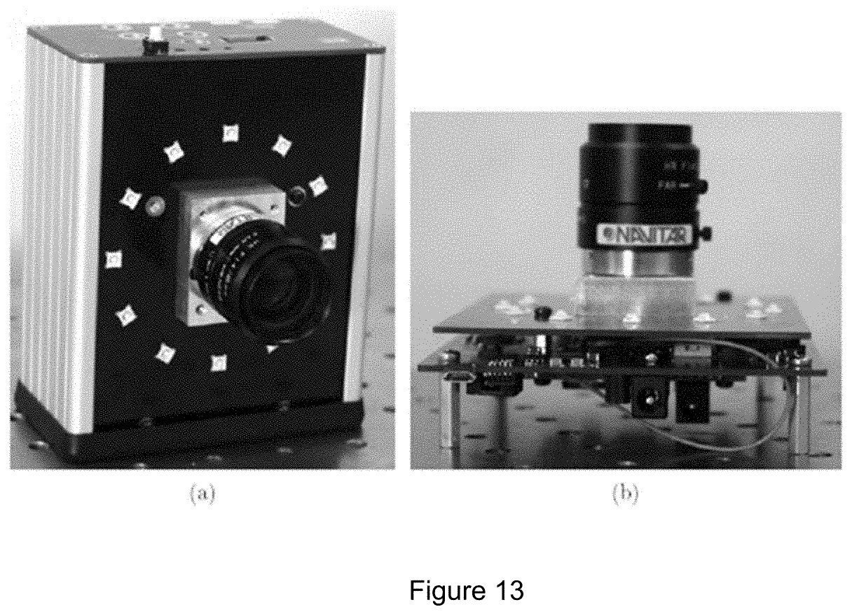

FIGS. 13(a) and 13(b) are images shows a prototype implementation of a 3D-imaging camera system 10 developed based on the monolithic SPAD/Photodiode image sensor 18, 16 described above.

### Operation as a Spatio-Temporal Event Camera

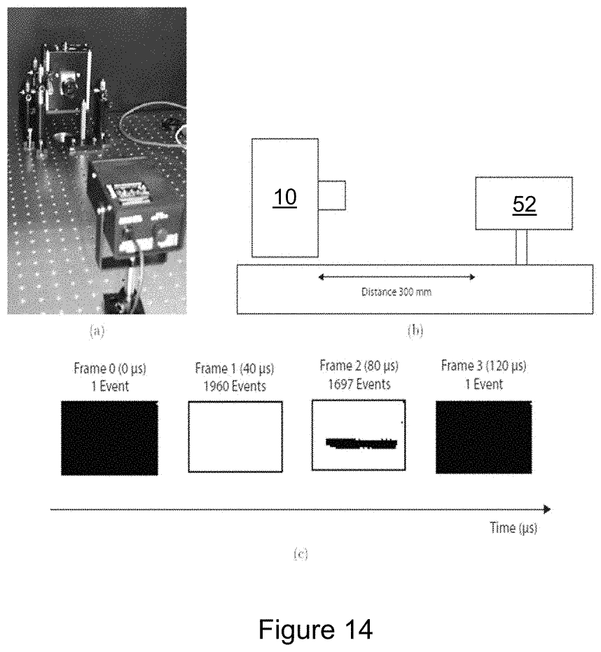

The uniformity of the photodiode array to a large positive spatio-temporal intensity change was measured using a strobe light. The strobe light 52 was used to produce a fast rise time bright pulse of light. Expected results are a spatio-temporal intensity increase at each pixel sufficiently large enough to produce an event at each pixel. These tests were conducted using a free running strobe light positioned directly in front of the sensor at a distance of 300 mm. A photo and schematic of the test setup are shown in FIG. 14(a) and FIG. 14(b) respectively.

The resultant images produced by this measurement are shown in FIG. 14(c). The strobe was unable to be triggered externally and the strobe fired at a time between 0 μs and 40 μs. This light pulse produced a positive intensity event on each of the photodiode pixels simultaneously (Frame 1). The subsequent image frames show light intensity that continues to increase (Frame 2) from the reflector and the decreasing intensity (Frame 3) after the end of the xenon arc flash in the strobe tube. These results confirm that the camera 10 is operating as a spatio-temporal detector.

### SPAD Photon Counting Imaging

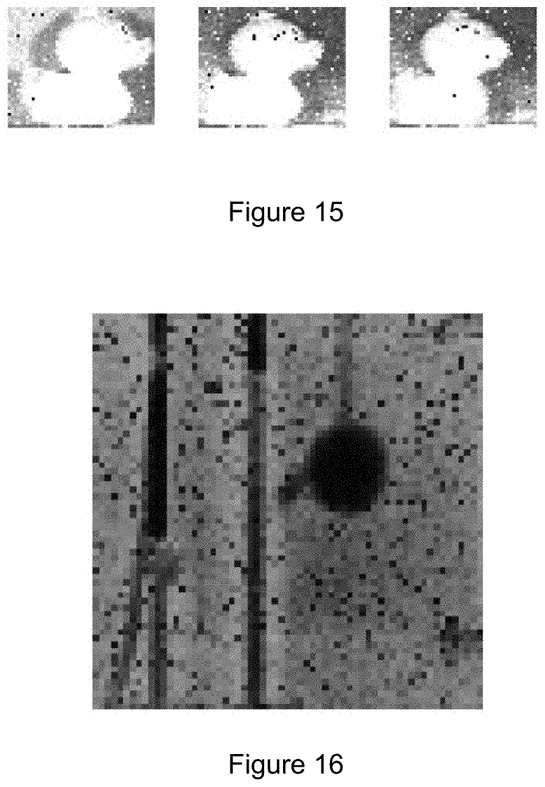

The SPAD sensor array 72 according to the described embodiment of the present invention is able to operate in photon counting mode. In this mode the sensor is able to produce images in a wide range of illumination levels effectively. Altering the exposure time alters the effective sensitivity of the pixels enabling operation in low light illumination environments. The dark count rate (DCR) presents a lower photon count rate limit to preserve the signal to noise ratio images. Example images captured using the photon counting mode are presented in FIG. 15. The images produced though photon counting mode are closely representative of those taken with a conventional frame based camera.

### SPAD Time of Flight Operation

SPAD time of flight measurements were conducted using a static table tennis ball 60 suspended on the optics table 56 using a string 55. Due to the minimum resolved depth being directly related to the maximum clock frequency of the SPAD array the depth resolution enabled the detection of the ball 60, string 55 and the optics posts 57 in front of the non-reflective background. These objects were measured to be at approximately the same distance from the camera 10 as each other as the light reflected light pulse arrived within a clock cycle period. The image produced though time of flight distance measurement is shown in FIG. 16. The maximum distance measured was limited to 10 m by the requirement for eye safety which restricted the illumination source to a low power light emitting diode (LED).

### Combined Mode Imaging

The advantages of the presented combined image sensor lies in its ability for combined simultaneous multi sensor image capture. To demonstrate the capabilities of the sensor a number of dynamic applications were chosen to present captured image data. The presented data is raw and unprocessed other than scaling to improve contrast. This data show the advantages of combined intensity and event information in tracking high speed objects.

### Ball Drop Imaging

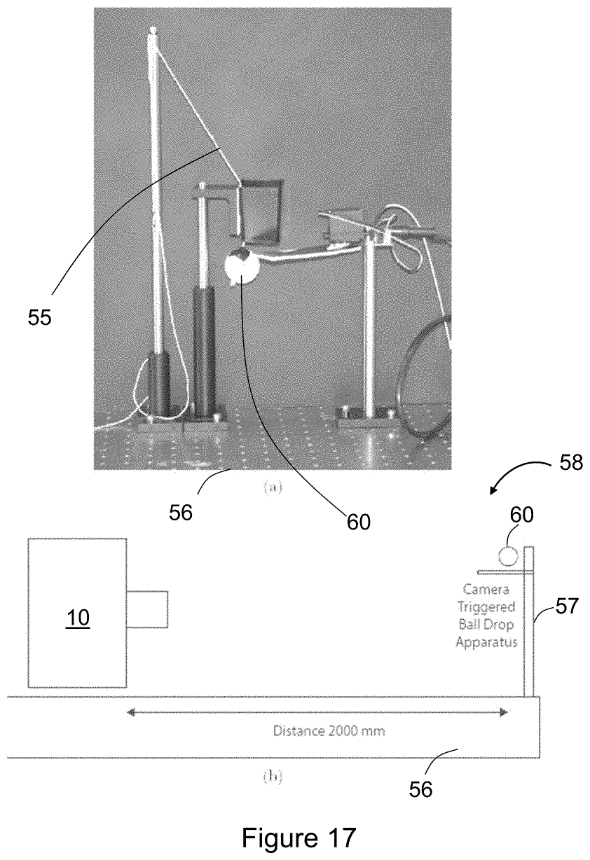

A table tennis ball 60 was dropped using a servo controlled by the host FPGA. The delay between the release of the ball 60 and capture of the image was able to be tuned to capture the flight of the ball down towards the optic table. A photo and schematic of the test setup 58 is shown in FIG. 17(a) and FIG. 17(b). FIG. 17(b) shows the setup used to capture an image of the ball 60 dropping from the ball drop apparatus 58. In the described setup, camera 10 is positioned at a distance of 200 mm from the ball drop apparatus 58. However, other distances can be choose for the experiment.

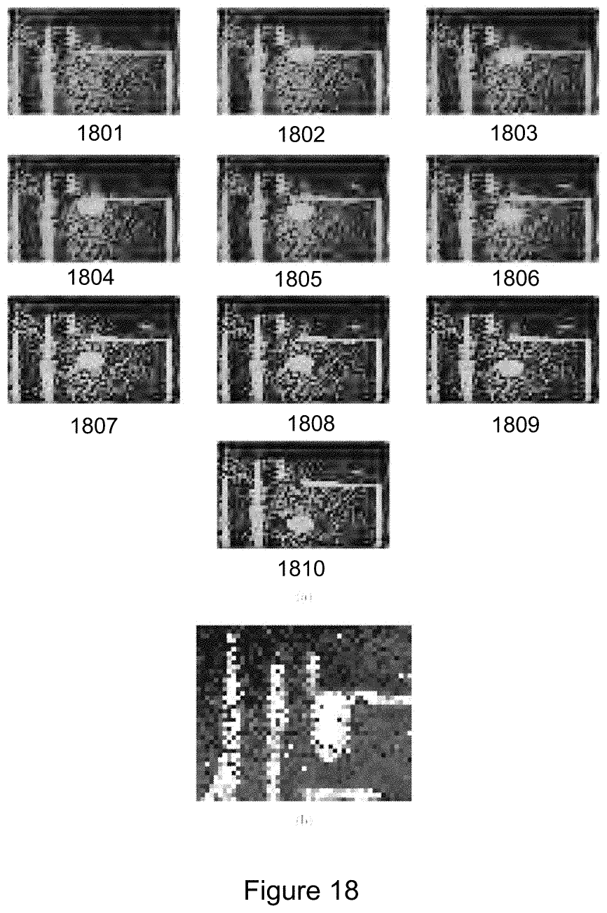

The logarithmic photodiode image capture produced results shown in FIG. 18(a) as images 1801-1810. The high image capture speed enabled tracking of the table tennis 60 ball along its trajectory. The images show limited distortion in the ball shape due to motion blur.

The images captured by the SPAD array in photon counting mode exhibit the behaviour shown in FIG. 18(b). The image clearly shows the accelerating ball as it travels down the frame. These images show the impact of the low frame rate achieved using photon counting due to the dynamic nature of the accelerating ball. The low fill factor of the SPAD sensors require a long exposure time to provide sufficient large numbers to produce visible images. The illumination levels in the laboratory were approximately 300 lux when these measurements were taken. Increased illumination reduces the required exposure time.

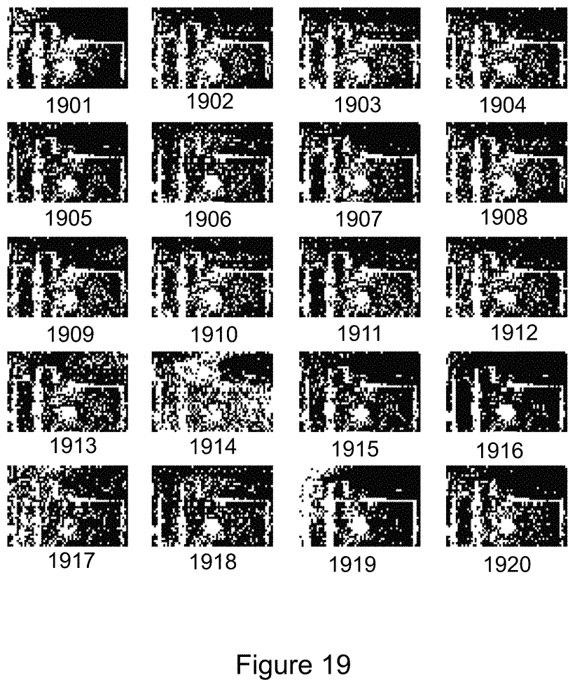

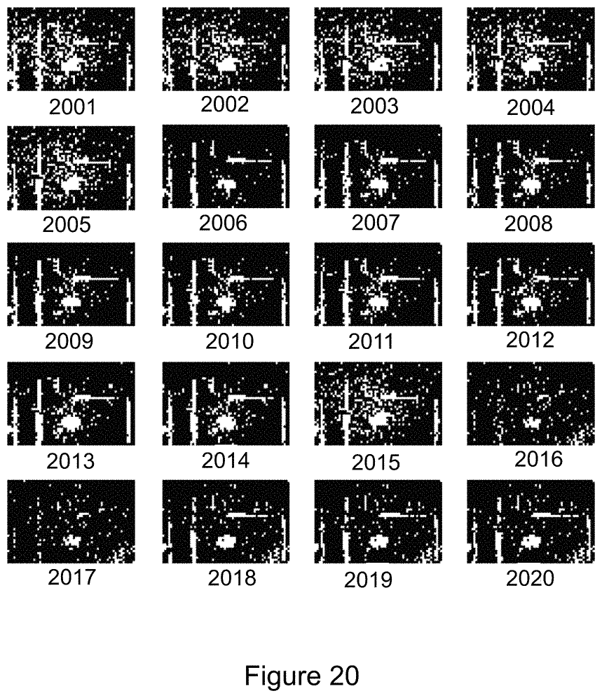

The images 1901-1910, 2001-2020 captured by the spatio-temporal event camera are shown in FIG. 19 and FIG. 20. The moving release mechanism as well as the falling ball can be seen in both the negative and positive events. A large number of events were produced by the dynamics of the system which included the movement of the optics posts during the release of the ball and moving servo controlled release mechanism.

### Rotating Fan Imaging

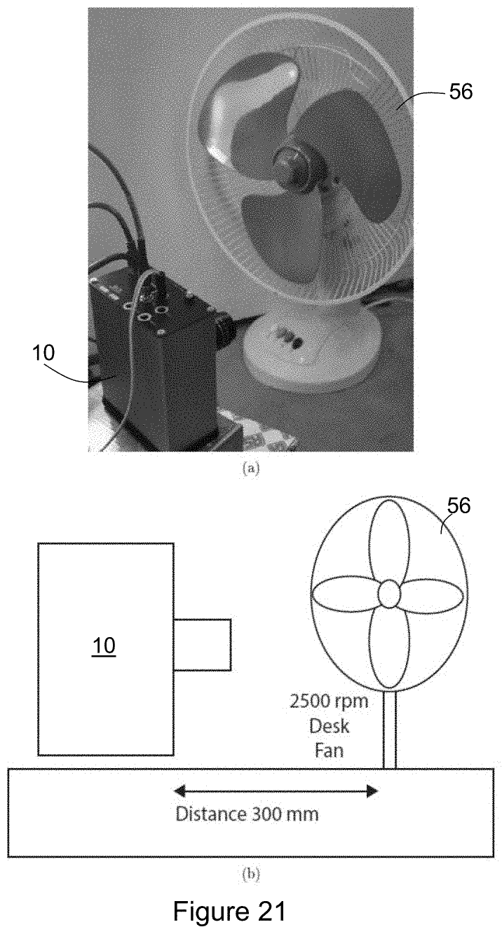

The dynamic imaging characteristics of the image sensor 14 are exhibited using a 2500 rpm desk fan 56. The imaging of the rotating blades highlighted the performance at high speed of both the event and logarithmic sensing systems. The camera 10 was placed approximately 250 mm from the rotating blades of the desk fan as shown in FIG. 21(a) and FIG. 21(b).

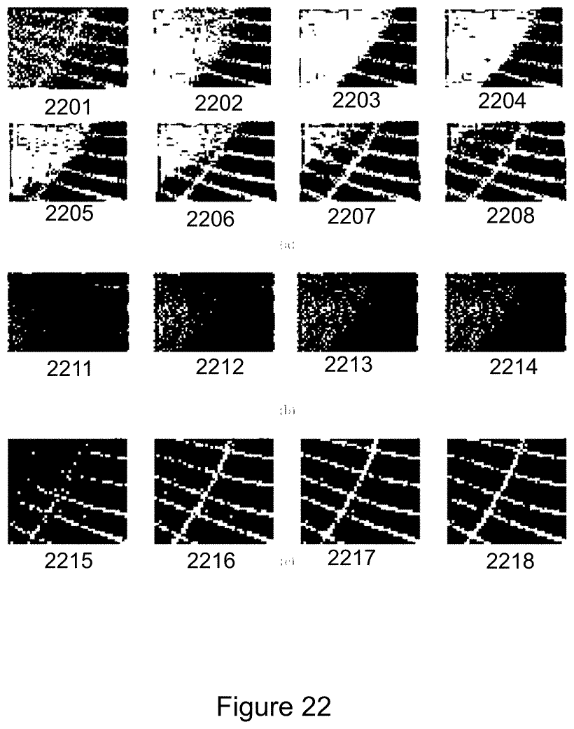

Images 2201-2208 captured using the logarithmic imaging system are shown in FIG. 22(a). The motion of the fan blades can be clearly observed progressing through the frames. The conventional global shutter imaging mode was also used to capture the rotating blades of the fan. The captured images 2211-2214 are shown in FIG. 22(b) which clearly demonstrate the effect of the smearing caused due to the required 100 μs exposure time to integrate sufficient light. The blades are no longer clearly discernible and instead show evidence of movement during the capture period.

SPAD photon counting was also used to capture image producing the images 2221-2224 shown in FIG. 22(c). As with the global shutter images, the fan blades are not clearly distinguishable. The static fan safety cage is clearly visible but only a shadow from the fan blades is present. A dynamic system shows the disadvantage of longer integration periods once more.

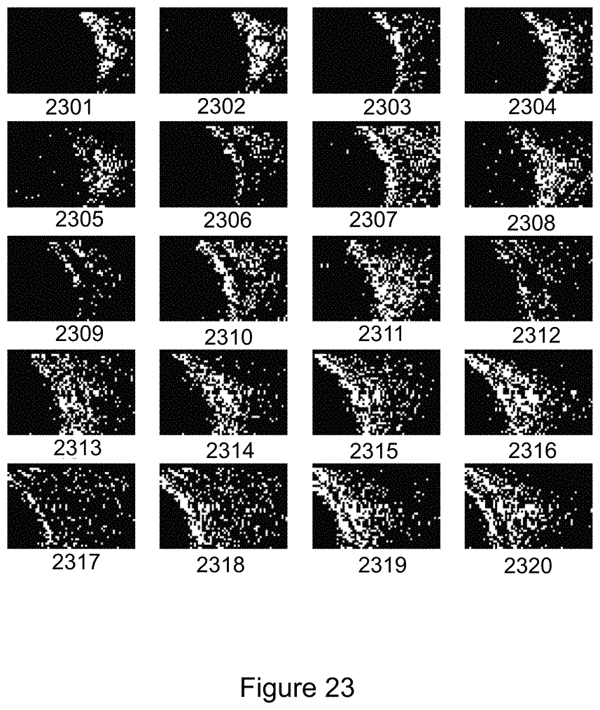

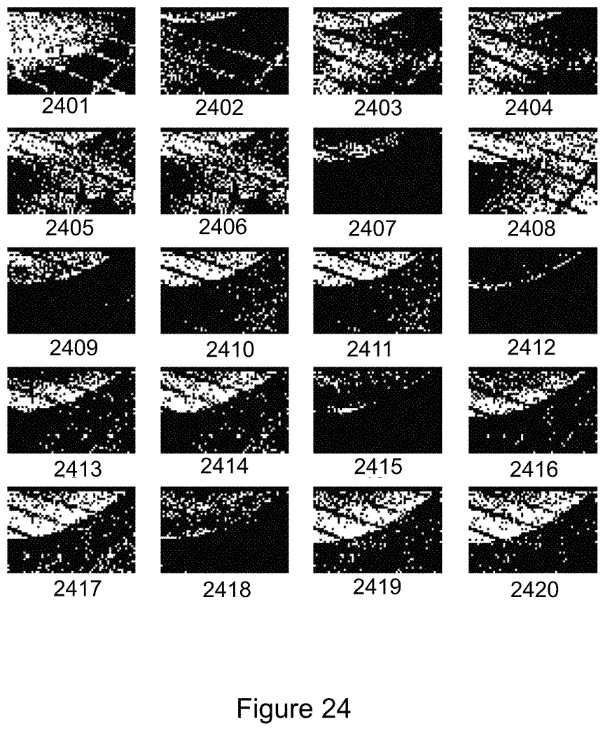

The results from the event camera for both positive and negative local intensity changes are. clearly visible in images 2301-2320 of FIG. 23 and images 2401-2420 of FIG. 24. The progression of the fan blades through the frames show the high-speed capture associated with the event camera readout. A large number of spatio-temporal events produced gives a clear edge of the fan blade as it progresses through the frame.

### Utility

The dual SPAD/photodiode 3D image sensor according to embodiments the present invention enables simultaneous time of flight 3D ranging, spatio-temporal event-based imaging, conventional frame based imaging and high dynamic range imaging. The sensor contains techniques that mimic elements of biological vision responding to relative changes in intensity rather than outputting redundant illumination data. This low latency event-based output enables high performance imaging with a sparse data output and minimises required computation overhead. The inclusion of co-located SPAD and photodiode sensors enable higher performance imaging than a system that uses only a single sensor type.

The dual sensor images apparatus, combines both SPAD and CMOS photodiode pixel in a single monolithic array and is amenable to the design of larger arrays. A single optical lens path is able to operate as a true 3D image sensor capturing simultaneous depth using the SPAD array to measure direct time of flight and intensity using the photodiode array. The system is capable of also simultaneously producing spatio-temporal event image data enabling microsecond latency localised intensity change events. The photodiode and SPAD arrays are able to operate simultaneously and independently in their various operating modes. The photodiodes are able to produce logarithmic instantaneous intensity or conventional global shutter intensity whilst simultaneously operating as a spatio-temporal event sensor. The SPAD array is able to operate in either photon counting mode or in time of flight mode. The resultant sensor is capable of producing high dynamic range images as a result of the photon counting of SPADs and logarithmic response of the photodiodes.

The use of spatio-temporal image capture in the embodiments requires the output of only pixels that have changed and therefore significantly decreases the data rate and the frame to frame latency. Embodiments of the invention output pixel events that directly encode localised illumination changes, reducing the data redundancy and increasing the timing resolution. This biologically inspired system improves the properties of the data output through: a sparse event-based data output format, only reporting relative luminance changes, and the encoding of both positive and negative signals into separate output channels. The resultant system is capable of microsecond event resolution at very low output data rates.

Whereas, conventional frame based imaging produces images that contain the absolute relative illumination intensity at each and every pixel in the frame, spatio-temporal image capture does not record the absolute intensity. The simultaneous capture of both the relative change and absolute illumination enables the production of images that are both high in fidelity and report changes with very low latency. In contrast, conventional frame based image sensors have a limited dynamic range.

The sensor array was designed in a commercial non-image sensor 0.13 μm HV CMOS process in order to provide sufficiently high voltage rated junctions for the SPAD diodes. The image sensor contains both high performance digital and analog circuitry.

The co-integration of a fully-integrated DC/DC converter and SPAD bias voltage control system increased the level of integration reducing the required overall system size. The inclusion of the electromagnetic interference (EMI) reduction techniques limited or avoided interference between the operation of the fully-integrated DC/DC converter with the sensitive photodiode sensor array due to. The SPAD bias control system enables temperature insensitive operation as the system is able to adjust to changing sensor performance due to changes in the operating conditions. The resultant 3D image sensor is ideal for use in applications where minimising total system size and mass is essential for operation, such as part of a micro UAS platform.

Sensor noise places a limit on the minimum reproducible light levels. Image sensors are unable to match the performance of human vision which is capable of enormous dynamic range and contrast sensitivity. The logarithmic receptors in the human eye enable this increased dynamic range. Embodiments of the invention propose logarithmic photodiode front-end circuits to increase the possible image sensor dynamic range to greater than 100 dB. Increased dynamic range enables a sensor to be used in many situations where both a wide range of illumination levels are likely to be encountered. Urban environments particularly present a challenge to conventional image sensors due to both natural and artificial lighting.

Advanced driver assistance systems have significantly decreased the cost and increased the availability of 3D ranging system. Sensor systems utilising radar or ultrasonics are widely implemented in modern vehicles. When these range sensors are combined with passive optical image sensors, autonomous operation or at the very least enhanced safety systems are able to improve the driving experience. Autonomous micro UASs require these sensor capabilities but have significantly more stringent payload restrictions than a motor vehicle. The monolithic image sensor system of embodiments of the invention is able to simultaneously capture the required data to enable pilot-less operation and maximum SLAM accuracy.

3D image sensor systems can utilise stereo or monocular vision. Stereo vision requires two sets of optics and image sensors that are physically offset from each other to capture depth. Monocular systems are able to measure distance but require an active illumination source. This trade-off between the additional sensor and optics system and the active illumination source points towards monocular systems having a lower total mass.

Time of flight measurement systems have been proposed using either direct or in-direct light measurement. Direct time of flight sensors are able to operate in the range of metres to kilometres. In-direct time of flight sensor systems are limited to near field measurements but provides greater range accuracy. Indirect time of flight is also more susceptible to multipath reflections particularly in poor weather conditions causing errors. For this application, direct time of flight was chosen for the increased range and improved noise immunity. Direct time of flight sensors directly measure the reflected light pulse and require high speed image sensors to provide the necessary accuracy. SPAD sensors are ideally suited for direct time of flight measurements as they offer pico-second response times to incident light.

Whilst the sensor according to an embodiment of the present invention is designed for use as the vision sensor for a micro UAS, there are many applications for which this image sensor would be suitable. These include high speed imaging, industrial vision, autonomous machine system vision, human interface devices, surveillance and visual prosthetics.

Modifications within the scope of the invention may be readily effected by those skilled in the art. It is to be understood, therefore, that this invention is not limited to the particular embodiments described by way of example hereinabove. For example, while the embodiments described in detail above relate to communication cables, it will be apparent that the invention may also be applied to other types of cable, including for electrical power transmission.

In the claims that follow and in the preceding description of the invention, except where the context requires otherwise owing to express language or necessary implication, the word “comprise” or variations such as “comprises” or “comprising” is used in an inclusive sense, that is, to specify the presence of the stated features but not to preclude the presence or addition of further features in various embodiments of the invention.

Further, any reference herein to prior art is not intended to imply that such prior art forms or formed a part of the common general knowledge in any country.

1. An imaging apparatus, comprising:
a semiconductor die;
a photosensitive array of photodiodes and single photon avalanche diodes (SPADs), the photodiodes comprising reverse biased diodes; and
a front-end circuit coupled to the photosensitive array; and
an output for outputting image data from the front-end circuit;
wherein the photosensitive array and the front-end circuit are provided in the semiconductor die.

2. (canceled)

3. The imaging apparatus as claimed in claim 1, wherein the photodiodes and the SPADs are arranged in an integrated manner in the semiconductor die or wherein the photodiodes and the SPADs are arranged in alternating rows in the semiconductor die or wherein the photodiodes alternate with the SPADs in rows in the semiconductor die.

4-5. (canceled)

6. The imaging apparatus as claimed in claim 1, wherein the photodiodes have an average density in the semiconductor die of approximately 200 per square millimetre and/or the SPADs have an average density in the semiconductor die of approximately 150 per square millimetre.

7. (canceled)

8. The imaging apparatus as claimed in claim 1, wherein the photodiodes are high speed photodiodes.

9. The imaging apparatus as claimed in claim 1, further comprising an electric power converter, an auto-bias and/or a temperature sensor.

10. The imaging apparatus as claimed in claim 1, wherein the front-end circuit comprises one or more of:
i) a timer for timing the detection of photons,
ii) a photon counter for counting photons detected by the SPADs,
iii) an avalanche quencher for halting avalanche multiplication of carriers in the SPADs,
iv) a reset circuit for resetting the SPADs after detection events,
v) a data serialiser for moving data out of the photosensitive array,
vi) an asynchronous event detector for detecting asynchronous changes in intensity in photons detected by the photodiodes,
vii) an intensity detector for determining instantaneous intensity of photons detected by the photodiodes,
viii) an integrated intensity detector measuring average intensity in photons detected by the photodiodes, and
ix) an analog to digital converter for directly converting photodiode voltage to a digital signal.

11. The imaging apparatus as claimed in claim 1, wherein the front-end circuit comprises a timer for timing the detection of photons and a photon counter for counting photons detected by the SPADs, and is configured to determine time of flight based on outputs of the timer and the photon counter.

12. The imaging apparatus as claimed in claim 1, wherein the apparatus is configured for acquiring hyperspectral 3D images.

13. The imaging apparatus as claimed in claim 1, comprising a lens train or a single lens for focusing incident light to an image on the photosensitive array.

14. (canceled)

15. The imaging apparatus as claimed in claim 1, wherein the front-end circuit implements analogue to digital converters (ADCs) for the photodiodes.

16. The imaging apparatus as claimed in claim 1, further comprising one or more microlenses located over some or all of the photodiodes and the SPADs to increase effective photosensitive area.

17. The imaging apparatus as claimed in claim 1, further comprising a wavelength selective filer located in the optical path to modify an incident photon spectrum.

18. The imaging apparatus as claimed in claim 1, wherein the photodiodes and the SPADs are configured to be simultaneously independently operated in different modes.

19. The imaging apparatus as claimed in claim 1, wherein either:
the SPADs are configured to capture time of flight depth data using an illumination source; and/or the SPADs are configured to capture intensity image data using a photon counting mode, and
the photodiodes are configured to capture intensity image data simultaneously.

20. (canceled)

21. The imaging apparatus as claimed in claim 1, wherein the photosensitive array and the front-end circuit are provided on the same side of the semiconductor die with the photosensitive and the front-end circuit array substantially facing the direction of the incident light or wherein the photosensitive array and the front-end circuit are provided on opposite faces of the semiconductor die with the photosensitive array substantially facing the direction of the incident light.

22. (canceled)

23. An imaging method, comprising:
collecting light with a photosensitive array of photodiodes and single photon avalanche diodes (SPADs) of the apparatus of claim 1; and
outputting image data from the front-end circuit;
wherein the photosensitive array and the front-end circuit are provided in a semiconductor die.

24. An imaging method, comprising:
collecting, using the apparatus of claim 1, time of flight data using the plurality of single photon avalanche diodes (SPADs), and simultaneously capturing image intensity data using the plurality of photodiodes; and
outputting the 3D image data from a front-end circuit.

25. An imaging method, comprising:
collecting, using the apparatus of claim 1, image intensity data using a photon counting mode of the plurality of single photon avalanche diodes (SPADs) and simultaneously capturing image intensity data using the plurality of photodiodes; and
outputting the image data from a front-end circuit.

26. A method of forming an imaging apparatus comprising:
forming, in a semi-conductor die, a photosensitive array of photodiodes and single photon avalanche diodes (SPADs), the photodiodes comprising reverse biased diodes; and
forming, in the semiconductor die, a front-end circuit coupled to the photosensitive array, the front-end circuit having an output for outputting image data from the front-end circuit.

27. The method as claimed in claim 26, comprising arranging the photodiodes and the SPADs in an integrated manner in the semiconductor die and either: arranging the photodiodes and the SPADs in alternating rows in the semiconductor die; or arranging the photodiodes to alternate with the SPADs in rows in the semiconductor die.

28. (canceled)

29. (canceled)
